(19) United States
(12) Patent Application Publication
(10) Pub. No.: US 2014/0071595 A1
(43) Pub. Date: Mar. 13, 2014

(54) LASER ABLATION ADHESION PROMOTION

(71) Applicants: Erik G. DE JONG, San Francisco, CA (US); Michael K. PILLIOD, San Francisco, CA (US); Chuan Keat LOW, Shenzhen (CN); James R. KROGDAHL, Cupertino, CA (US); Rimple BHATIA, Woodside, CA (US)

(72) Inventors: Erik G. DE JONG, San Francisco, CA (US); Michael K. PILLIOD, San Francisco, CA (US); Chuan Keat LOW, Shenzhen (CN); James R. KROGDAHL, Cupertino, CA (US); Rimple BHATIA, Woodside, CA (US)

(73) Assignee: Apple Inc., Cupertino, CA (US)

(21) Appl. No.: 13/607,513

(22) Filed: Sep. 7, 2012

(51) Int. Cl. B32B 37/06; B32B 37/12; B32B 3/10; H05K 5/03

(52) U.S. Cl. 361/679.01; 156/272.8; 428/201

(57) ABSTRACT

A method for bonding two substrates can use a laser to ablate a bonding surface of at least one of the two substrates. In one embodiment, the laser can be used to produce a predetermined average surface roughness in a bonding surface region of one of the substrates. In another embodiment, the substrate can comprise a resin filled polymer. Ablating the surface of the bonding surface can increase the bond strength in the ablation region.

### FIELD OF THE DESCRIBED EMBODIMENTS

The described embodiments relate generally to bonding substrates together and more particularly to forming a bond between two substrates using laser ablation on one or more bond surfaces disposed on the substrates.

### BACKGROUND

The bond strength of a bond between a first substrate and a second substrate bonded through an adhesive can be affected by many factors. First of all the affinity of the first substrate and the second substrate to a selected adhesive can affect the wetting of the bond area and thereby affect the resulting bond strength. Another factor can be the mechanical properties of the selected adhesive, such as an ultimate bond strength and sensitivity to strain rate. A third factor for bond strength can be in regards to mechanical properties of the bond interface area. For example, an ultimate strength of the substrate material and sensitivity to strain rate of substrate material in the bond area can be an important factor for bond strength.

In some cases, a product design may not have enough degrees of freedom to allow the designer enough choices to formulate a relatively strong bond between substrates. For example, a selected substrate may have a poor bonding characteristics with a particular adhesive. However, the may be no design flexibility in the choice of substrate material and, furthermore, the choices for an adhesive may be limited because required operating conditions, required tack or other adhesive working characteristics.

Therefore, what is desired is a way to bond substrates together that can produce relatively strong bonds while maintaining substrate choices.

### SUMMARY OF THE DESCRIBED EMBODIMENTS

This paper describes various embodiments that relate to bonding a first substrate to a second substrate including laser ablating at least one substrate.

One method for bonding a first substrate to a second substrate can include the steps of laser ablating a first bond surface of the first substrate, where the first bond surface is less than the entire first substrate, disposing an adhesive onto a first bond surface on the second substrate, where the first bond surface on the second substrate corresponds to the first bond surface on the first substrate, and bonding the second substrate to the first substrate by placing the adhesive in direct contact with the first bond surface of the first substrate.

In another embodiment, another method for bonding a first substrate to a second substrate can include the steps of laser ablating a first bond surface of the first substrate, where the first bond surface is less than the entire first substrate, of laser ablating a first bond surface of the second substrate, where the first bond surface is less than the entire second substrate, disposing an adhesive onto a first bond surface on the second substrate, where the first bond surface on the second substrate corresponds to the first bond surface on the first substrate, and positioning the adhesive to be in direct contact with the first bond surface of the first substrate.

In yet another embodiment, a housing can include a rear cover including at least one opening, where the rear cover is configured to contain electrical components for the portable electronic device and including a laser ablated bonding surface, a front cover, configured to be clear and fit into the at least one opening of the rear cover and configured to have a bonding surface matching the bonding surface of the rear cover, a display unit placed within the rear cover and positioned behind that front cover, and an adhesive applied on the first bonding surface of the rear cover.

A bonded assembly can include a first substrate with a laser ablated bonding surface less than the entire first substrate, a second substrate with a first bonding surface corresponding to the shape of the bonding surface of the laser ablated bonding surface and an adhesive layer disposed between the first bonding surface of the first substrate and the first bonding surface of the second substrate.

Other aspects and advantages of the invention will become apparent from the following detailed description taken in conjunction with the accompanying drawings which illustrate, by way of example, the principles of the described embodiments.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1 is a cross section of a prior art bond formed between a first substrate and a second substrate.

FIG. 2 is a cross section illustration of a bond between a first substrate, a second substrate using laser ablation in accordance with one embodiment described in the specification.

FIG. 3 is a cross section illustration of another bond between a first substrate, the second substrate using laser ablation in accordance with one embodiment described in the specification.

FIG. 4 is a cross section illustration of yet another bond 400 between the first substrate, a second substrate using laser ablation in accordance with one embodiment described in the specification.

FIG. 5 is a cross sectional view of housing for a portable electronic device that can include a bond that can be formed with laser ablation.

FIG. 6 is flow chart of method steps for bonding a first and a second substrate together using laser ablation to pretreat the substrates.

### DETAILED DESCRIPTION OF SELECTED EMBODIMENTS

Representative applications of methods and apparatus according to the present application are described in this section. These examples are being provided solely to add context and aid in the understanding of the described embodiments. It will thus be apparent to one skilled in the art that the described embodiments may be practiced without some or all of these specific details. In other instances, well known process steps have not been described in detail in order to avoid unnecessarily obscuring the described embodiments. Other applications are possible, such that the following examples should not be taken as limiting.

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting; such that other embodiments may be used, and changes may be made without departing from the spirit and scope of the described embodiments.

Often a bond between a first substrate and a second substrate can have a limited bond strength. The bond strength can be limited because of substrate choice and because of adhesive bonding characteristics between a selected adhesive and the first and/or the second substrate. For example an affinity between the adhesive and the first surface can be relatively poor reducing a resulting bond strength between the first and the second substrates. In some designs, there may be little flexibility in adhesive choice because of operating conditions or assembly limitations, for example.

In one embodiment a bond surface on the first substrate can be ablated by a laser. The ablation can increase the average surface roughness to a predetermined amount. In another embodiment, the first substrate can be formed from a filled polymer resin. Laser ablation of a filled polymer resin can remove a smooth skin on the first substrate that can be a result of a molding (such as injection molding) operation and can expose at least a portion of the filler material included in the filled resin polymer. In another embodiment, a bond surface on the first and the second substrates can be laser ablated prior to an application of an adhesive to bond the first substrate to the second substrate.

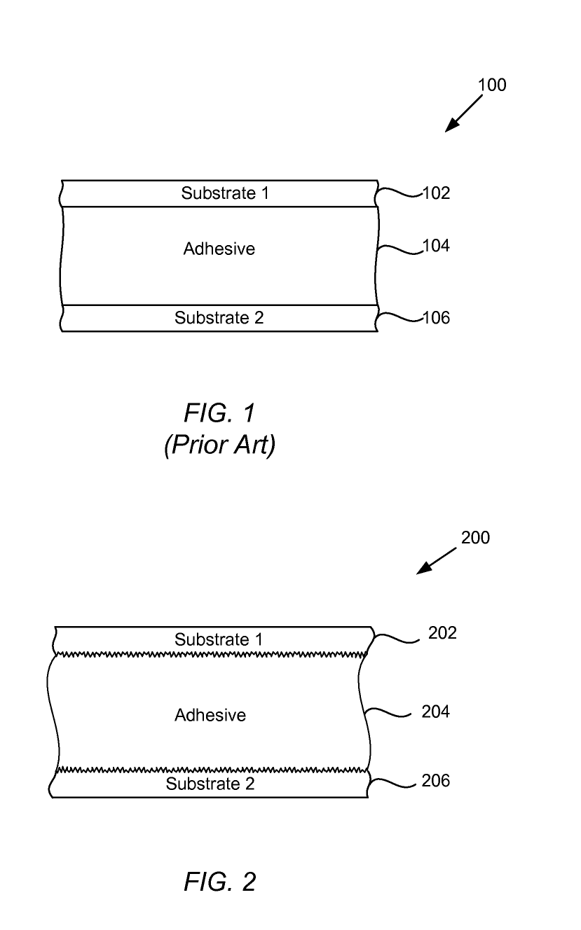

FIG. 1 is a cross section of a prior art bond 100 formed between a first substrate 102 and a second substrate 106 with an adhesive 104. The first and the second substrates 102, 106 can be formed from any appropriate material. For example, the substrates 102, 106 can be polymers such as filled and un-filled resins, metallic substrates such as aluminum, titanium, metal alloys, formed metal such as formed sheet metal, or other materials such as wood or glass. Adhesives 104 can be disposed between the first substrate 102 and the second substrate 106 to bond the substrates together. Adhesives 104 can be pressure sensitive, thermo or UV curing or any other technically feasible adhesive. In some designs, however adhesive choices may be limited due to manufacturing (limitations on the line) or operating constraints (such as operating temperature extremes or required operating humidity). As a result, a bond may be limited in strength especially when the selected adhesive 104 can have a relatively poor bond strength with either the first substrate 102 or the second substrate 106 or, in some cases, poor bond strength with both substrates.

FIG. 2 is a cross section illustration of a bond 200 between a first substrate 202, a second substrate 206 and an adhesive 204 in accordance with one embodiment described in the specification. The first substrate 202 and the second substrate 206 can be substrates as described above in FIG. 1. Bond areas on first substrate 202 and second substrate 206 can be treated with laser ablation to enhance the strength of a bond near the area of the laser ablation. The bond area can be an area on a first surface of the first substrate that is configured to receive the adhesive 204. Similarly, the bond area on the second substrate can be an area on a first surface of the second substrate that is configured to receive the adhesive 204.

Laser ablation can increase a surface roughness on the bond areas of the first and second substrates, and thereby increase bond strength in the bond areas. In one embodiment, laser ablation can increase an average surface roughness of the bond area to a predetermined amount. In one embodiment, first substrate can be molded from composite material such as a filled polymer resin. Oftentimes, molded composite parts can include a relatively smooth outer layer relatively rich in resin material, especially when compared to the bulk of the molded part. Laser ablation can increase the average roughness of the outer layers of molded composite parts.

Laser ablation of the bond areas of the first and the second substrates can provide more adhesive choices to the designer. The bond performance, in this example, is no longer limited to the bond strength between the adhesive 104 and the first substrate 102. Laser ablation of the first substrate can alter surface roughness, surface chemistry and surface composition and thereby affect the material in contact with adhesive 204. Thus, in some embodiments, bond strength can be increased substantially by laser ablation.

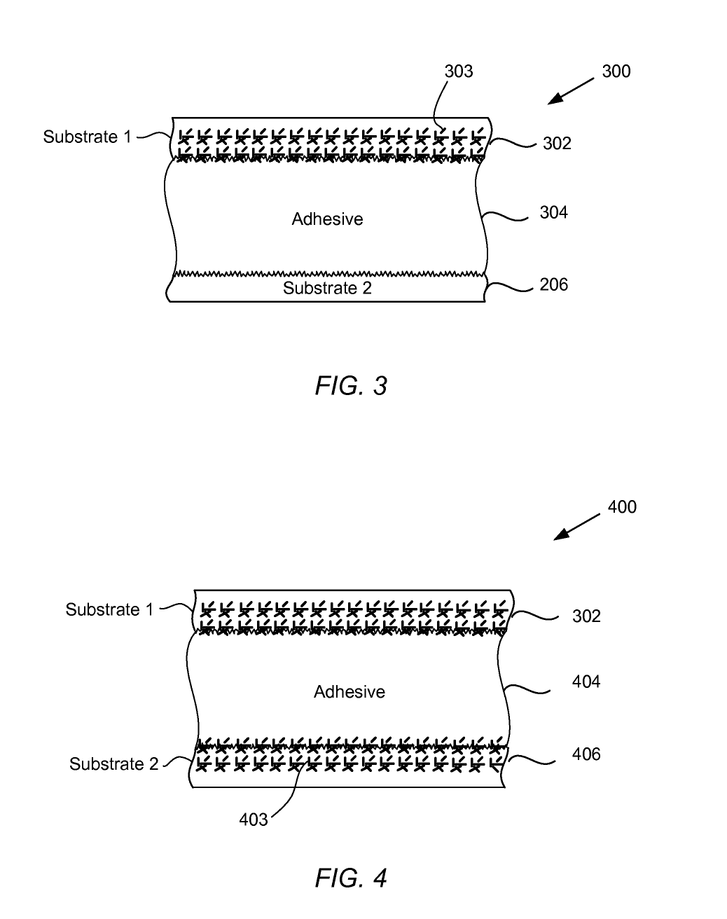

FIG. 3 is a cross section illustration of a bond 300 between a first substrate 302, the second substrate 206 formed with an adhesive 304 in accordance with one embodiment described in the specification. In this embodiment, the second substrate 206 can be as described in FIG. 2. In one embodiment, the first substrate 302 can be a composite such as a filled polymer resin. Filler material 303 is schematically shown with first substrate 302. In this example, the first substrate 302 is laser ablated in a bond area that will receive the adhesive 304. As described above, laser ablation can increase the average roughness of the first substrate 302. In this example, since first substrate 302 is a composite, laser ablation can expose filler material of the composite substrate. In yet another embodiment, the adhesive 204 can have a higher affinity for the filler material 303 than the first substrate 302; thus, exposing the filler material can increase bond strength. Adhesive 304 can be selected to bond first ablated substrate 302 to second ablated substrate 206.

FIG. 4 is a cross section illustration of a bond 400 between the first substrate 302, a second substrate 406 formed with an adhesive 404 in accordance with one embodiment described in the specification. The first substrate 302 can be as described above in FIG. 3. In this embodiment, the second substrate 406 can also be a composite, similar to the first substrate 302. Both bond surfaces of the first substrate 302 and the second substrate 406 can be laser ablated to enhance bond strength. In one embodiment, bond surfaces can be less than the entire first or second substrate 302, 406 respectively. Filler material 403 is shown schematically within second substrate 406. Adhesive 404 can be applied to either substrate (first substrate 302 or second substrate 406) in the laser ablated areas to bond the substrates together.

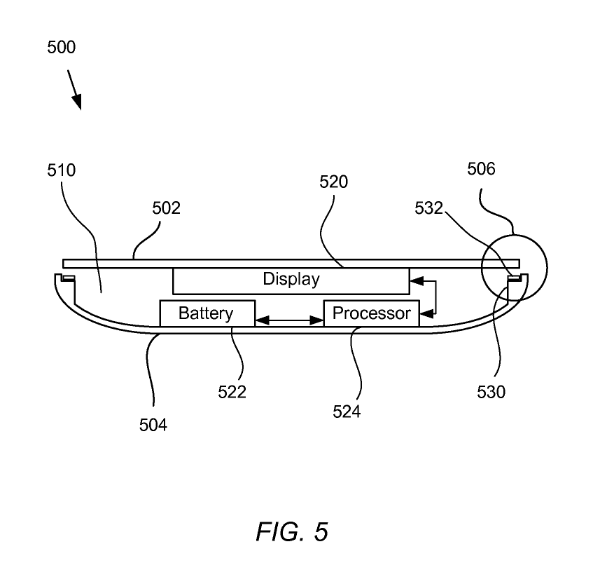

FIG. 5 is a cross sectional view of housing 500 for a portable electronic device that can include a bond that can be formed with laser ablation. The housing 500 can include a front cover 502 and a rear cover 504. The housing 500 can contain components related to the portable electronic device such as a display 520, a processor 524 and a battery 522. In one embodiment, front cover 502 can be substantially transparent and allow at least a portion of the display 520 to be seen through front cover 502. The processor 524 can be configured to control the display 520 and display images on the display 520 for the user. The battery 522 can provide power for the processor 524 and the display 520.

The rear cover 504 can include at least one opening 510 that can receive the processor 524, the battery 522 and the display 520. In one embodiment, the rear cover 504 can include a mounting feature 530 that can be integral to rear cover 504, or can be formed of a material different from the rear cover 504 and secured in place with any technically feasible means such glue, epoxy, welding or the like. The front cover 502 can be configured to substantially fit within at least one opening 510 in the front cover 502. At least one bond area is shown within area 506. In one embodiment, mounting feature 530 can be laser ablated prior to the application of an adhesive 532 to the mounting feature 530. Front cover 502 can be affixed to the adhesive 532. In one embodiment, bond areas on the front cover 502 can be laser ablated prior to the application of adhesive 532.

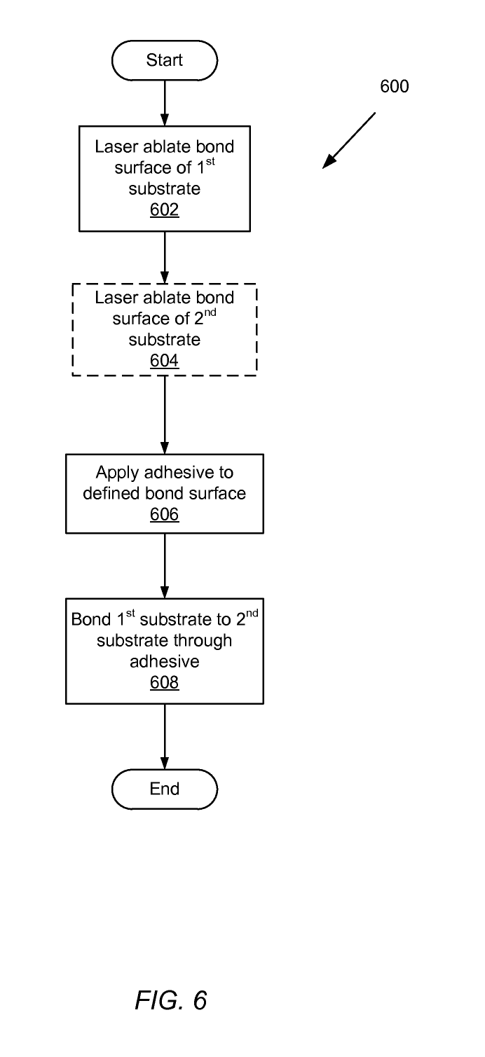

FIG. 6 is flow chart 600 of method steps for bonding a first and a second substrate together using laser ablation to pretreat the substrates. Persons skilled in the art will understand that any system configured to perform the method steps in any order is within the scope of this description. The method begins in step 602, where a first bond surface of the first substrate can be laser ablated. In one embodiment, the laser ablation can be limited to a bond area less than an entire area of the first substrate. The method can proceed to step 604, when a bond area of the second substrate is laser ablated. Step 604 can be an optional step (as shown with dashed lines). In other words, each substrate need not be laser ablated, especially when laser ablating only one substrate can provide a bond of sufficient strength. In step 606, an adhesive is applied to the bond area. In one embodiment, the adhesive is only applied to the bond area of one substrate (that is, either the first substrate or the second substrate, but not both). In step 608, the first substrate is bonded to the second substrate through the adhesive and the method ends. In one embodiment, the applied adhesive is placed in contact with the bond surfaces on both the first and the second substrates.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium for controlling manufacturing operations or as computer readable code on a computer readable medium for controlling a manufacturing line. The computer readable medium is any data storage device that can store data which can thereafter be read by a computer system. Examples of the computer readable medium include read-only memory, random-access memory, CD-ROMs, HDDs, DVDs, magnetic tape, and optical data storage devices. The computer readable medium can also be distributed over network-coupled computer systems so that the computer readable code is stored and executed in a distributed fashion.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

What is claimed is:

1. A method for bonding a first substrate to a second substrate, with an adhesive comprising:
preparing a first bond surface on the first substrate, the first bond surface less than the entire first substrate, by laser ablating the first bond surface;
disposing an adhesive on a first bond surface of the second substrate, wherein the first bond surface of the second substrate substantially corresponds to the first bond surface on the first substrate; and
bonding the second substrate to the first substrate by placing the adhesive disposed on the first bond surface of the second substrate in direct contact with the first bond surface of the first substrate.

2. The method of claim 1, wherein the average roughness of the first bond surface of the first substrate is increased to a predetermined average amount.

3. The method of claim 1, wherein the first substrate is a filled polymer resin.

4. The method of claim 3, wherein the laser ablation exposes filler material from the filled polymer resin.

5. The method of claim 4, wherein the second substrate is a substantially clear.

6. A method for bonding a first substrate to a second substrate, with an adhesive comprising:
preparing a first bond surface on the first substrate, the first bond surface less than the entire first substrate, by laser ablating the first bond surface on the first substrate;
preparing a first bond surface on the second substrate, the first bond surface less than the entire second substrate, by laser ablating the first bond surface on the second substrate;
disposing an adhesive on a first bond surface of the second substrate, wherein the first bond surface of the second substrate substantially corresponds to the first bond surface of the first substrate; and,
positioning the adhesive to be in direct contact with the first bond surface of the first substrate.

7. The method of claim 6, wherein at least one of the first substrate or the second substrate the first substrate comprises a filled polymer resin and wherein the laser ablation removes a smooth resin finish and exposes at least a portion of the filler material

8. A housing for a portable electronic device comprising:
a rear cover including at least one opening and a laser ablated first bonding surface proximate to the at least one opening, wherein the rear cover is configured to contain electrical components for the portable electronic device;
a front cover configured to be substantially clear and sized to substantially fit into the at least one opening of the rear cover and configured to include a first bonding surface substantially matching the shape of the first bonding surface of the rear cover;
a display unit disposed within the rear cover, wherein the display unit is positioned behind the front cover so that at least a portion of the display is visible through the front cover; and,
an adhesive applied on the first bonding surface of the rear cover, wherein the adhesive is placed in direct contact with the first bonding surface of the front cover.

9. The housing of claim 8, wherein the first bonding surface of the rear cover comprises a filled resin polymer.

10. The housing of claim 9, wherein the laser ablating removes at least a portion of the surface of the filled resin polymer.

11. The housing of claim 10, wherein the laser ablating exposes filler material included in the filled resin polymer.

12. The housing of claim 8, wherein the laser ablating increases an average roughness of the first bonding surface of the rear cover to a predetermined amount.

13. The housing of claim 8, wherein the first bonding surface of the front cover is laser ablated prior to the application of the adhesive.

14. A bonded assembly comprising:
a first substrate with a laser ablated first bonding surface, wherein the first bonding surface is less than the entire first substrate;
a second substrate with a first bonding surface corresponding to the shape of the first bonding surface of the first substrate; and
an adhesive layer disposed between the first bonding surface of the first substrate and first bonding surface of the second substrate.

15. The bonded assembly of claim 14, wherein the laser ablation increases the average surface roughness of the first bonding surface of the first substrate to a predetermined amount.

16. The bonded assembly of claim 15, wherein the first bonding surface comprises a filled polymer resin.

17. The bonded assembly of claim 16, wherein the laser ablation exposes at least a portion of the filler material in the filled polymer resin.

18. The bonded assembly of claim 14, wherein the first bonding surface of the second substrate is laser ablated prior to bonding with the first substrate.

19. The bonded assembly of claim 18, wherein the second substrate comprises a resin filled polymer.

20. The bonded assembly of claim 19, wherein the laser ablating exposes filler material on at least one of the first or the second substrates.
